(19) United States
(12) Patent Application Publication
(10) Pub. No.: US 2017/0294630 A1
(43) Pub. Date: Oct. 12, 2017

(54) VERFAHREN ZUM HERSTELLEN EINES LATERAL STRUKTURIERTEN, ORGANISCHEN, LICHTEMITTIERENDEN BAUELEMENTES UND LATERAL STRUKTURIERTE, ORGANISCHE, LICHTEMITTIERENDE BAUELMENTE

(71) Applicant: OSRAM OLED GmbH, Regensburg (DE)

(72) Inventors: Tobias Hero, Regensburg (DE); Richard Baisl, Regensburg (DE)

(21) Appl. No.: 15/485,266

(22) Filed: Apr. 12, 2017

(30) Foreign Application Priority Data
Apr. 12, 2016 (DE) 10 2016 106 723.7

(51) Int. Cl. H01L 51/56; H01L 27/32; H01L 51/52

(52) U.S. Cl. CPC H01L 51/56; H01L 51/5253; H01L 51/5268; H01L 27/3239; H01L 2251/5315

(57) ABSTRACT

In various embodiments, a method for producing an organic light-emitting component is provided. The method includes forming an electrically active region and applying an adhesion-medium layer on or above the electrically active region. The adhesion-medium layer includes a magnetic material distributed in an adhesion medium. The magnetic material is embedded as particles in the adhesion medium. The method furthermore includes applying an alternating magnetic field to the adhesion-medium layer such that the adhesion medium forms at least one adhesive connection, wherein an adhesive connection is formed between the adhesion medium and the electrically active region. The adhesion-medium layer is formed in such a way, and/or the alternating magnetic field is configured in such a way that the adhesion-medium layer has a lateral structuring after the adhesive connection has been formed.

### RELATED APPLICATIONS

The present application claims priority from German application No.: 10 2016 106 723.7 filed on Apr. 12, 2016, and is incorporated herein by reference in its entirety.

### TECHNICAL FIELD

Various embodiments relate to a method for producing an organic light-emitting component and to an organic light-emitting component.

### BACKGROUND

A conventional light-emitting component, for example an OLED, includes an electrically active region having an anode, a cathode and an organic functional layer system therebetween. The electrically active region is conventionally encapsulated in order to protect it against mechanical damage. In addition, the encapsulation protects the electrically active region against water and/or oxygen. A conventional encapsulation includes a glass cover for example, which is laminated onto the electrically active region by means of an adhesive.

The curing of the adhesive for encapsulating organic components places stringent demands on process speed and reliability in series production of the components on account of short cycle times. Furthermore, on account of the large difference in refractive index from adhesive to electrically active region and glass cover, a large part of the light generated in the organic functional layer system is not coupled out, but rather remains in the organic functional layer system or the glass cover.

Hitherto the adhesive has been cured by a thermal curing process, for example in a furnace, and/or by a UV exposure. During curing, the organic functional layer system is subjected, for a relatively long period of time, to a thermal load that is unnecessary for the organic functional layer system. This can lead to crystallization, degradation, crosslinking and/or diffusion of the organic material of the organic functional layer system.

In order to increase the coupling-out of the light from the light-emitting component, i.e. from the glass cover and/or the organic functional layer system, conventionally a film including scattering centres also referred to as a scattering film is laminated above the electrically active region.

### SUMMARY

Various embodiments provide a method for producing an organic light-emitting component and same in which the thermal loading of the organic functional layer structure is reduced. Further embodiments set the emission characteristic of the organic light-emitting component in a simpler manner.

In one aspect, a method for producing an organic light-emitting component is provided. The method includes forming an electrically active region and applying an adhesion-medium layer on or above the electrically active region. The adhesion-medium layer includes a magnetic material distributed in an adhesion medium. The method furthermore includes applying an alternating magnetic field to the adhesion-medium layer, such that the adhesion medium forms at least one adhesive connection.

In various embodiments, the magnetic material is for example a paramagnetic material, a diamagnetic material or a ferromagnetic material. The ferromagnetic material has a large hysteresis area and thus brings about a heat transfer to the adhesion medium in a small number of cycles of the alternating magnetic field.

In other words: by means of the magnetic material and the alternating magnetic field an adhesive connection is formed at the adhesion medium of the adhesion-medium layer. By way of example, the adhesion medium is cured. The alternating magnetic field is homogenous or inhomogeneous, for example.

In various developments, the magnetic material and the adhesion medium are thermally coupled to one another. This brings about a heat flow between the magnetic material and the adhesion medium.

In various developments, the adhesion medium is substantially transparent to visible light and at least part of the light emittable by the light-emitting component is emittable through the adhesion-medium layer. This makes it possible that the magnetic material can influence the beam path of the light being transmitted. As a result, the emission characteristic of the organic light-emitting component can be set in a simple manner.

In various developments, the magnetic material is embedded as particles in the adhesion medium. This enables simple setting of the coupling area between magnetic material and adhesion medium and thus enables simple setting of the parameters of the alternating magnetic field in order to form the adhesive connection.

In one development, the magnetic particles are formed such that they are light-scattering. This has the effect, by means of the light-scattering magnetic particles in the adhesion-medium layer, that the light modes otherwise guided in the electrically active region can be coupled out by means of volume scattering.

By virtue of the variably adjustable size of the scattering particles and the variably adjustable magnetic field distribution, it is possible in a targeted manner to have a positive influence on the emission characteristic of the organic light-emitting component, and to improve for example the colour rendering index CRI, the saturation and/or the emission range of the organic light-emitting component.

In various developments, the magnetic particles are arranged in the adhesion medium with respect to a predefined direction and/or structure before the adhesive connection is formed, for example by means of a homogeneous magnetic field. In the case of non-radially symmetrical magnetic particles, the predefined direction can be for example an alignment of the particles with respect to a predefined direction. A predefined structure is for example a predefined relative arrangement of the magnetic particles with respect to one another, for example in order to represent information.

By way of example, by means of a targeted setting of the distribution of the magnetic field used, it is possible to influence the distribution, for example the arrangement and/or the number density, of the magnetic particles in the adhesion-medium layer. This makes it possible to be able in a targeted manner to influence the emission spectrum of the organic light-emitting component. By way of example, firstly by means of magnetic migration the magnetic particles can be arranged with respect to a predefined arrangement in the organic light-emitting component, for example be concentrated in a predefined range. For this purpose, the adhesion medium has for example a lower viscosity than after the adhesive connection has been formed. In a further method step, the magnetic particles that have been arranged can be exposed to the alternating magnetic field in order to cause the adhesive connection to be formed.

In various developments, an adhesive connection is formed between the adhesion medium and the electrically active region. This brings about a more reliable encapsulation of the organic light-emitting component.

In various developments, the method furthermore includes forming a thin-film barrier layer on the electrically active region, and applying the adhesion-medium layer on the thin-film barrier layer. An adhesive connection is formed between the adhesion medium and the thin-film barrier layer.

In various developments, the method furthermore includes arranging a cover on the adhesion-medium layer before the adhesion medium forms the adhesive connection. A further adhesive connection is formed between the adhesion medium and the cover by means of the alternating magnetic field.

By combining the process for laminating the cover and the simultaneous alignment of the magnetic particles contained in the adhesion medium, it is possible to combine two production steps. This leads to shorter throughput times in series production. Furthermore, the thermal load on the organic materials used is reduced since heat is generated locally for a short time only in the adhesion-medium layer as a result of the induction.

In various developments, the alternating magnetic field is applied to the adhesion-medium layer in a predefined region, such that at least one adhesive connection is formed only in the predefined region.

In various developments, the magnetic material is a ferrite and the magnetic material is demagnetized after the adhesive connection has been formed, for example by means of a component-external neodymium magnet.

This has the effect that the magnetization of the magnetic particles does not or does not significantly influence the current flow in the organic light-emitting component.

In various aspects an organic light-emitting component is provided which includes an electrically active region and an adhesion-medium layer on or above the electrically active region. The adhesion-medium layer includes magnetic particles embedded in an adhesion medium. The magnetic particles are arranged in a predefined arrangement in the adhesion medium.

This enables a targeting setting of the optical electrical and magnetic properties of the organic light-emitting component.

In various developments, the adhesion-medium layer includes at least one adhesive connection in a predefined first region and a second region arranged alongside the first region which is free of said adhesive connection.

In various developments, the magnetic particles are formed and arranged in the adhesion-medium layer in such a way that information is representable by means of the magnetic particles. The information can be read optically and/or magnetically, for example. The information can be for example lettering or an image.

In various developments, the light-emitting component is formed at least as a top emitter, for example as a bidirectionally or omnidirectionally light-emitting component.

In various developments, the organic light-emitting component has the same features as the method for producing the organic light-emitting component, and vice versa.

### BRIEF DESCRIPTION OF THE DRAWINGS

In the drawings, the same reference signs generally refer to the same parts in the different views. The drawings are not necessarily true to scale, emphasis being given essentially to illustrating the principles of the embodiments disclosed. In the following description, various embodiments are described with reference to the following drawings, in which:

FIG. 1 shows, in schematic cross-sectional views, a flow diagram of a method for producing an organic light-emitting component in accordance with various embodiments;

FIG. 2 illustration of one embodiment of an organic light-emitting component; and

FIGS. 3A-C show, in schematic cross-sectional views, excerpts from a flow diagram of a method for producing an organic light-emitting component including a laterally structured adhesion-medium layer in accordance with various embodiments.

### DETAILED DESCRIPTION

In the following detailed description, reference is made to the accompanying drawings which form part of this description and show for illustration purposes specific embodiments in which the various embodiments can be implemented. Since component parts of embodiments can be positioned in a number of different orientations, the direction terminology serves for illustration and is not restrictive in any way whatsoever. It goes without saying that other embodiments can be used and structural or logical changes can be made, without departing from the scope of protection of the present various embodiments. It goes without saying that the features of the various embodiments described herein can be combined with one another, unless specifically indicated otherwise. Therefore, the following detailed description should not be interpreted in a restrictive sense, and the scope of protection of the present various embodiments is defined by the appended claims. In the figures, identical or similar elements are provided with identical reference signs, insofar as this is expedient.

An organic light-emitting assembly may include one, two or more organic light-emitting components. Optionally, an organic light-emitting assembly may also include one, two or more electronic components. An electronic component may include for example an active and/or a passive component. An active electronic component may include for example a computing, control and/or regulating unit and/or a transistor. A passive electronic component may include for example a capacitor, a resistor, a diode or a coil.

An organic light-emitting component can be an electromagnetic radiation-emitting component. In various embodiments, an electromagnetic radiation-emitting component can be an electromagnetic radiation-emitting semiconductor component and/or be formed as an electromagnetic radiation-emitting diode, as an organic electromagnetic radiation-emitting diode, as an electromagnetic radiation-emitting transistor or as an organic electromagnetic radiation-emitting transistor. The radiation can be for example light in the visible range, UV light and/or infrared light. In this context, the electromagnetic radiation-emitting component can be formed for example as a light-emitting diode (LED) as an organic light-emitting diode (OLED), as a light-emitting transistor or as an organic light-emitting transistor. In various embodiments, the light-emitting component can be part of an integrated circuit. Furthermore, a plurality of light-emitting components can be provided, for example in a manner accommodated in a common housing.

In accordance with various configurations, the light-emitting component (e.g. organic light-emitting component such as e.g. OLED) can be embodied as a “bottom emitter”.

The term “bottom emitter” or “bottom emitting light-emitting component”, as used herein, denotes an embodiment which is embodied as transparent towards the substrate side of the light-emitting component.

By way of example, for this purpose, at least the substrate and layers formed between the substrate and the at least one functional layer (e.g. an electrode (bottom electrode) formed between substrate and functional layer(s)) can be embodied as transparent. A light-emitting component embodied as a bottom emitter can accordingly emit radiation generated for example in the functional layers (e.g. organic functional layers in the case of an organic light-emitting component such as e.g. an OLED) on the substrate side of the light-emitting component.

As an alternative or in addition thereto, the light-emitting component in accordance with various embodiments can be embodied as a “top emitter”.

The term “top emitter” or “top emitting light-emitting component”, as used herein, denotes for example an embodiment which is embodied as transparent towards the side of the light-emitting component facing away from the substrate (to put it another way towards the top side). In particular, for this purpose, the layers formed on and/or above the at least one functional layer of the light-emitting component (e.g. electrode (top electrode) formed between functional layer(s) and thin-film barrier layer, thin-film barrier layer, intermediate layer, cover layer) can be embodied as transparent. A light-emitting component embodied as a top emitter can accordingly emit radiation generated for example in the functional layers (e.g. organic functional layers in the case of an organic light-emitting component such as e.g. an OLED) on the top side of the light-emitting component.

A light-emitting component configured as a top emitter in accordance with various embodiments can advantageously have a high coupling-out of light and a very small angle dependence of the radiance. A light-emitting component in accordance with various embodiments can advantageously be used for lighting systems, such as room luminaries, for example.

A combination of bottom emitter and top emitter is likewise provided in various embodiments. In the case of such an embodiment, the light-emitting component is generally able to emit the light generated in the functional layers (e.g. the organic functional layers in the case of an organic light-emitting component such as e.g. an OLED) in both directions—that is to say both towards the substrate side and towards the top side—(transparent or translucent OLED).

The term “translucent” or “translucent layer” can be understood to mean that the layer is transmissive to light, for example to the light generated by the organic light-emitting component. By way of example, the term “translucent layer” should be understood to mean that substantially the entire quantity of light coupled into the layer is also coupled out from the layer, wherein part of the light is scattered in the process. The term “transparent” or “transparent layer” can be understood to mean that the layer is transmissive to light, wherein light coupled into the layer is also coupled out from the layer substantially without scattering or light conversion.

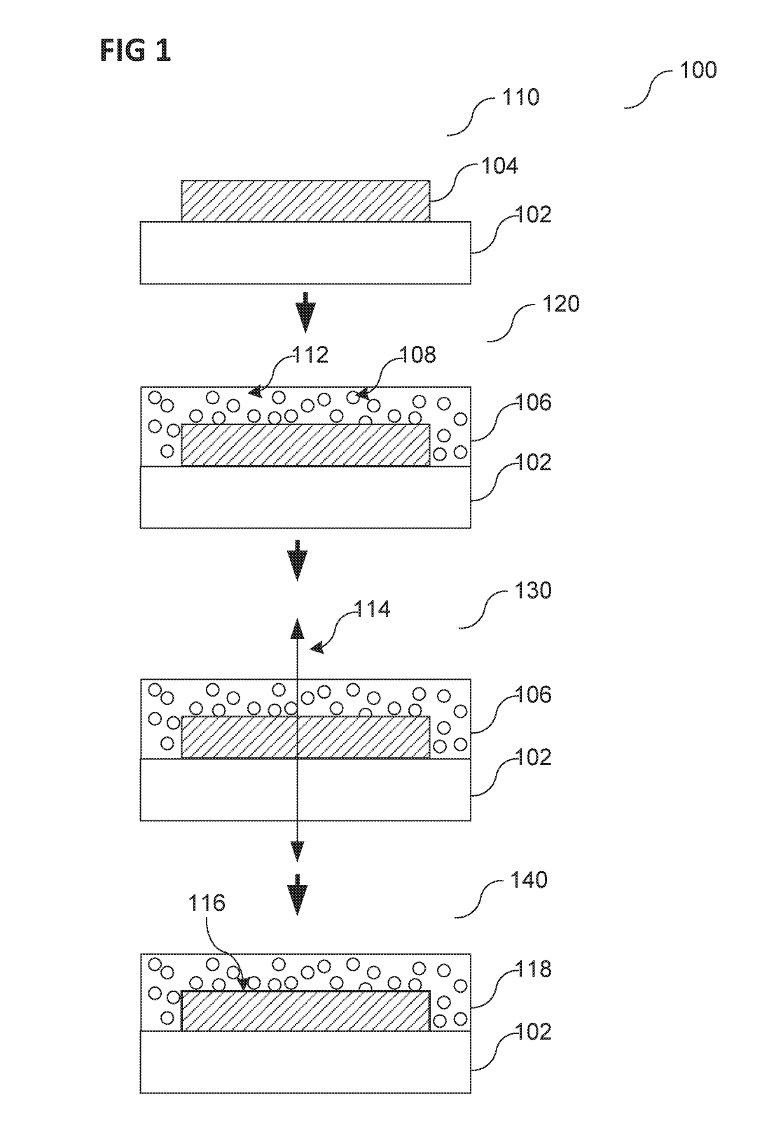

FIG. 1 shows, in schematic cross-sectional views, a flow diagram of a method 100 for producing an organic light-emitting component in accordance with various embodiments.

The method 100 includes forming 110 an electrically active region 104 on or above a substrate 102.

Furthermore, the method 100 includes applying 120 an adhesion-medium layer 106 on or above the electrically active region 104. The adhesion-medium layer 106 includes a magnetic material 108 distributed in an adhesion medium 112.

Furthermore, the method 100 includes applying 130 an alternating magnetic field 114 to the adhesion-medium layer 106, such that the adhesion medium 112 forms at least one adhesive connection 116—illustrated as an adhesion-medium layer 118 with adhesive connection 116 in the further method step 140.

The magnetic material has a hysteresis curve in an alternating magnetic field. The area enclosed by the hysteresis curve of the magnetic material is the energy per unit volume of the magnetic material which is expended in the course of the magnetization passing from the positive saturation flux density Bₛ to the negative saturation flux density −Bₛ and the subsequent return from −Bₛ to Bₛ. Said energy is liberated as heat during the magnetization process. The supplied heat substantially corresponding to the area of the hysteresis curve leads to an increase in the temperature of the magnetic material. The change in temperature of the magnetic material is thus approximately proportional to the quantity of heat from the area of the hysteresis curve.

The magnetic material and the adhesion medium, for example the adhesive, of the adhesion-medium layer are thermally coupled to one another via a common area. By means of the alternating magnetic field and the ensuing increase in temperature of the magnetic material, a temperature difference is formed between the magnetic material and the adhesion medium. As a result, a heat flow flows from the magnetic material to the adhesion medium.

By means of the heat flow, an increase in the temperature of the adhesion medium and an increase in the stored heat of the adhesion medium occur, as a result of which, when a predefined temperature specific to the adhesion medium is exceeded, the adhesion medium can manifest an adhering or adhesive effect depending on the concrete configuration of the adhesion medium.

The magnetic material is for example a magnetically hard material, as a result of which the area of the hysteresis curve is larger than in the case of a magnetically soft material. A magnetically hard material has a high remanence Br, a high saturation flux density Bs and/or a high coercive field Hc. This results in a large hysteresis area and thus a high energy per unit volume of the magnetic material which can be converted into heat. The process time and the number of cycles of the alternating magnetic field can be reduced as a result. Moreover, magnetically hard materials are more resistant to small disturbances of the magnetization by external magnetic fields, heat or impacts. This has the effect that the alignment of the magnetic material in the adhesion medium is stabler.

The process of applying the alternating magnetic field to the adhesion-medium layer, causing the alternating magnetic field to act on the adhesion-medium layer or exposing the adhesion-medium layer to the alternating magnetic field can be carried out by the component being guided through a constant magnetic field in method step 120. Alternatively, in method step 120, the component can be arranged in a positionally invariant manner between the pole shoes of an electromagnet whose magnetic field strength and direction are changed over time.

The heat transferred to the adhesion medium should be limited in such a way that the temperature of the organic functional layer structure is less than approximately 120° C. Otherwise the organic material of the electrically active region could be thermally loaded. In other words: the heat for forming the adhesive connection, for example for curing the adhesion medium, is generated only locally in the adhesion-medium layer. As a result, temperatures of greater than 150° C. can occur locally in the adhesion-medium layer. It is important, therefore, that the heat in the organic functional layer structure remains less than approximately 120° C., for example less than 100° C., for example less than 80° C.

The increase in temperature of the adhesion medium, depending on the concrete adhesion medium, can bring about an acceleration of the extraction of a solvent present, a chemical reaction, for example a crosslinking reaction, melting and/or curing.

In various developments, the adhesion medium is substantially transparent to visible light and at least part of the light emittable by the light-emitting component is emittable through the adhesion-medium layer.

The adhesion medium is, for example, a chemically curing adhesive, i.e. an adhesive in the case of which the adhesive connection is formed by means of a chemical reaction. A chemically curing adhesive is for example a polymerization adhesive, a polycondensation adhesive or a polyaddition adhesive. A polymerization adhesive is for example a cyanoacrylate adhesive, a methyl methacrylate adhesive, an anaerobically curing adhesive, an unsaturated polyester (UP resins) or a radiation-curing adhesive. A polycondensation adhesive is for example a phenol formaldehyde resin adhesive, a silicone, a silane-crosslinking polymer adhesive, a polyimide adhesive or a polysulphide adhesive. A polyaddition adhesive is for example a silicone, epoxy resin or polyurethane.

Alternatively, the adhesion medium is a physically curing adhesive, for example a hot melt adhesive, a solvent-containing wet adhesive, a contact adhesive, a dispersion adhesive, a water-based adhesive or a plastisol.

Depending on the concrete constitution of the adhesion medium the adhesion-medium layer can be applied in the form of a film, granules, a block or a solution on or above the electrically active region. The magnetic material can be distributed, embedded or dissolved in the adhesion medium during the process of applying the adhesion medium on or above the electrically active region. Alternatively, the magnetic material is distributed, embedded or dissolved in the adhesion medium before and/or after the process of applying the adhesion medium on or above the electrically active region.

In various developments, the magnetic material is embedded as particles in the adhesion medium. In other words: the magnetic material is distributed in particulate form in the adhesion medium. The magnetic particles can be formed such that they are light-scattering.

The magnetic material can be configured for example in the form of metallic or oxidic particles, for example nanoparticles. The magnetic material may include or be for example Au, Ag, Ti, In, TiO₂, Fe₂O₃.

With regard to their shape and dimensioning, the magnetic particles can be formed such that they are light-scattering or be non-scattering for light.

In various developments, before the adhesive connection is formed, for example before the curing of the adhesion medium, the magnetic particles are arranged in the adhesion medium with respect to a predefined direction or alignment and/or structure, for example by means of a homogenous magnetic field that brings about a magnetic migration of the magnetic particles. By means of the inductive method used and a variable setting of the magnetic field density, for example using Helmholtz coils, it is possible to achieve a targeted alignment of the magnetic particles contained in the adhesion-medium layer before or during the process of applying the alternating magnetic field to the adhesion-medium layer, exposing the adhesion-medium layer to the alternating magnetic field or causing the alternating magnetic field to act on the adhesion-medium layer.

In various developments, the alternating magnetic field is applied to the adhesion-medium layer in a predefined region, such that at least one adhesive connection is formed only in the predefined region. In other words: in some developments, the adhesive connection is formed in a structured fashion. By way of example, an adhesive connection is formed only in a predefined, first region, for example in the optically inactive edge region of the organic light-emitting component. A second region, for example the optically active region, i.e. light-emitting region, of the organic light-emitting component, which region is surrounded by the optically inactive region, can be free of adhesive connection.

By way of example, a first type of magnetic material and/or particles can be arranged in the first region and a second type of magnetic material and/or particles can be arranged in the second region. The first type and the second type can have for example different magnetic properties, for example differently sized areas of the hysteresis curves. Alternatively or additionally, the coupling area of the magnetic material with the adhesion medium can be different for the first type and the second type. By way of example, the particles in the first region are smaller than in the second region given the same or approximately the same proportion by volume of the magnetic material in the adhesion-medium layer in the respective region. Alternatively or additionally, the first region can have a higher proportion by volume and/or a higher distribution or number density of magnetic material than the second region. Alternatively or additionally, an inhomogeneous alternating magnetic field can be used for forming the adhesive connection. By way of example, the magnetic field strength can be greater in the first region compared with in the second region.

By means of forming the adhesion-medium layer in a structured fashion, it is possible, for example, to set the light scattering, i.e. the emission characteristic of the organic light-emitting component, for example to represent information, for example a symbol, lettering, a pictogram or the like. Furthermore, forming the adhesive connection can bring about an increase in the hardness of the adhesion-medium layer. By means of forming the adhesive connection in a structured fashion, it is possible to form a region which has a lower hardness and thus a better mechanical damping than the region with adhesive connection.

In various developments, an adhesive connection is formed between the adhesion medium and the electrically active region. Alternatively, the method includes forming a thin-film barrier layer on the electrically active region, and applying the adhesion-medium layer on the thin-film barrier layer. An adhesive connection is then formed between the adhesion medium and the thin-film barrier layer.

In various developments, the method furthermore includes arranging a cover or a covering body on the adhesion-medium layer before the adhesion medium forms the adhesive connection. A further adhesive connection can be formed between the adhesion medium and the cover by means of the alternating magnetic field.

In various developments, the magnetic material is a ferrite and the magnetic material is demagnetized after the adhesive connection has been formed, for example after the curing of the adhesion medium, for example by means of a component-external neodymium magnet.

In various developments, the adhesion-medium layer including the magnetic material is applied on or above the electrically active region and an adhesive connection is formed. In other words: the adhesion-medium layer thus formed forms the outer layer (capping layer) of the organic light-emitting component. Alternatively, before the adhesion-medium layer is formed, a covering body is arranged on the adhesion-medium layer. In this case, the covering body forms the outer layer of the organic light-emitting component. Alternatively, a further, second adhesion-medium layer is applied on the first adhesion-medium layer after the adhesive connection has been formed, i.e. on the first adhesion-medium layer already treated using the alternating magnetic field. The second adhesion-medium layer can be formed in accordance with one of the described configurations of an adhesion-medium layer. By means of the second adhesion-medium layer, by way of example, the covering body can be arranged on or above the first adhesion-medium layer and be connected for example by means of an adhesive connection. The second adhesion-medium layer can be formed identically or differently to the first adhesion-medium layer. By way of example, the second adhesion-medium layer can have a different, for example lower, hardness than the first adhesion-medium layer. Alternatively or additionally, the second adhesion-medium layer may include a different type of magnetic particles, for example magnetic particles having a different shape or size. This enables a particle gradient and thus simple setting of optical properties.

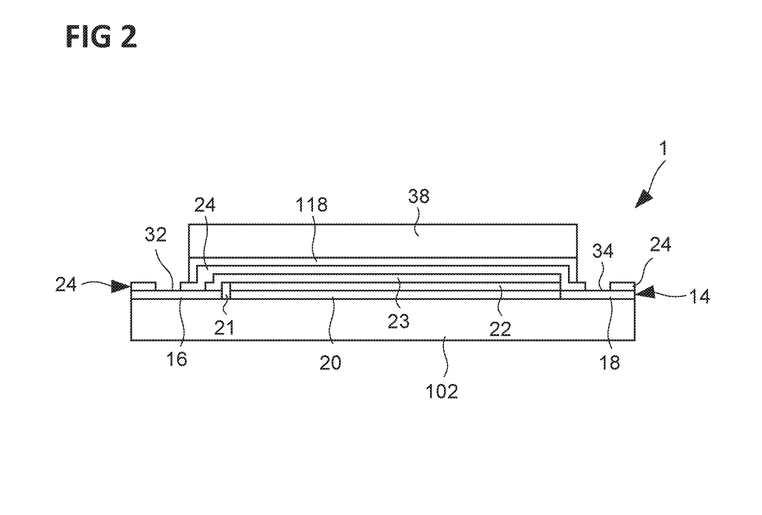

FIG. 2 shows a schematic sectional view of an organic light-emitting component 100 which for example can largely correspond to the embodiment shown in FIG. 1.

The organic light-emitting component includes an electrically active region on the substrate and an adhesion-medium layer on or above the electrically active region. The adhesion-medium layer includes magnetic particles embedded in an adhesion medium. The magnetic particles are arranged in a predefined arrangement in the adhesion medium.

The electrically active region includes a first electrode layer including a first contact section 16, a second contact section 18 and the first electrode 20.

The electrode 20 is electrically insulated from the first contact section 16 by means of an electrical insulation barrier 21. The second contact section 18 is electrically coupled to the first electrode 20.

The electrode 20 can be formed as an anode or as a cathode. The electrode 20 can be formed as translucent or transparent. The electrode 20 includes an electrically conductive material, for example metal and/or a transparent conductive oxide TCO or a layer stack of a plurality of layers including metals or TCOs. The electrode 20 may include for example a layer stack of a combination of a layer of a metal on a layer of a TCO, or vice versa. One example is a silver layer applied on an indium tin oxide layer (ITO) (Ag on ITO) or ITO-Ag-ITO multilayers. The electrode 20 may include as an alternative or in addition to the stated materials: networks composed of metallic nanowires and nanoparticles, for example composed of Ag, networks composed of carbon nanotubes, graphene particles and graphene layers and/or networks composed of semiconducting nanowires.

The organic functional layer structure 22 is formed on the first electrode 20, said organic functional layer structure being configured for example for emitting light and likewise being a part of the electrically active region. The organic functional layer structure 22 may include for example one, two or more partial layers. By way of example, the organic functional layer, structure 22 may include a hole injection layer, a hole transport layer, an emitter layer, an electron transport layer and/or an electron injection layer. The hole injection layer serves for reducing the band gap between first electrode 20 and hole transport layer. In the case of the hole transport layer, the hole conductivity is greater than the electron conductivity. The hole transport layer serves for transporting the holes. In the case of the electron transport layer, the electron conductivity is greater than the hole conductivity. The electron transport layer serves for transporting the electrons. The electron injection layer serves for reducing the band gap between second electrode and electron transport layer. Furthermore, the organic functional layer structure 22 may include one, two or more functional layer structure units each including the stated partial layers and/or further intermediate layers.

The second electrode 23 is formed above the organic functional layer structure 22, which second electrode can also be referred to as second electrode 23 and is likewise part of the electrically active region. The second electrode 23 is electrically coupled to the first contact section 16. The second electrode 23 can be formed in accordance with one of the configurations of the first electrode 20, wherein the electrode 20 and the second electrode 23 can be formed identically or differently. The electrode 20 serves for example as an anode or a cathode of the active region. The second electrode 23 serves as a cathode or an anode of the active region in a manner corresponding to the first electrode.

A getter structure (not illustrated) can be arranged on or above the active region, said getter structure being part of the encapsulation structure 112. The getter layer can be formed as translucent, transparent or opaque. The getter layer may include or be formed from a material that absorbs and binds substances that are harmful to the active region.

An encapsulation structure is formed above the second electrode 23 and partly above the first contact section 16 and partly above the second contact section 18.

In various developments, the encapsulation structure includes the adhesion-medium layer 118, an encapsulation layer 24 and/or a cover 38.

Furthermore, the encapsulation structure may include an encapsulation layer 24 which is formed on the active region and encapsulates the latter. The encapsulation layer 24 can be formed as a barrier layer, for example as thin-film barrier layer 24. The encapsulation layer 24 can also be referred to as thin-film encapsulation. The encapsulation layer 24 forms a barrier with respect to chemical contaminants and/or atmospheric substances, in particular with respect to water (moisture) and oxygen. The encapsulation layer 24 can be formed as a single layer, a layer stack or a layer structure. The encapsulation layer 24 may include or be formed from: aluminium oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminium-doped zinc oxide, poly(p-phenylene terephthalamide), nylon 66, and mixtures and alloys thereof. If appropriate, a further barrier layer can be formed on the substrate 102, i.e. between the substrate 102 and the active region, in a manner corresponding to a configuration of the encapsulation layer 24.

In the encapsulation layer 24, a first cutout of the encapsulation layer 24 is formed above the first contact section 16 and a second cutout of the encapsulation layer 24 is formed above the second contact section 18. A first contact region 32 is exposed in the first cutout of the encapsulation layer 24 and a second contact region 34 is exposed in the second cutout of the encapsulation layer 24. The first contact region 32 serves for electrically contacting the first contact section 16 and the second contact region 34 serves for electrically contacting the second contact section 18.

The adhesion-medium layer 118 which is part of the encapsulation structure is formed on the encapsulation layer 24 or alternatively on the electrically active region. The adhesion-medium layer 118 includes, for example, as already described above an adhesion medium, for example an adhesive, for example a lamination adhesive, a lacquer and/or a resin. The magnetic particles of the adhesion-medium layer 118 can be configured for scattering electromagnetic radiation, for example as magnetic light-scattering particles.

In various developments, a covering body 38 is formed above the adhesion-medium layer 118, said covering body likewise being part of the encapsulation structure. The covering body 38 can also be referred to as cover 38. The adhesion-medium layer 118 serves for securing the covering body 38 on the encapsulation layer 24 or the electrically active region. The covering body 38 includes for example plastic, glass and/or metal. By way of example, the covering body 38 can substantially be formed from glass and include a thin metal layer, for example a metal film, and/or a graphite layer, for example a graphite laminate, on the glass body. The covering body 38 serves for protecting the conventional light-emitting component 1, for example against mechanical force influences from outside. Furthermore, the covering body 38 can serve for distributing and/or dissipating heat that is generated in the conventional light-emitting component 1. By way of example, the glass of the covering body 38 can serve as protection against external influences and the metal layer of the covering body 38 can serve for distributing and/or dissipating the heat that arises during operation of the conventional light-emitting component 1.

In various developments, the covering body 38 is formed as substantially transparent, for example in the case of an organic light-emitting component that is formed at least as a top emitter. The organic light-emitting component can be formed for example as a bidirectionally or omnidirectionally light-emitting component.

Alternatively, the covering body can be formed as reflective or specularly reflective, for example for an organic light-emitting component of bottom emitter design. In this case, light-scattering magnetic particles can change the angle of incidence on the covering body 38.

In various developments, the adhesion-medium layer includes at least one adhesive connection in a predefined first region and a second region arranged alongside the first region, said second region being free of said adhesive connection.

In various developments, the magnetic particles are formed and arranged in the adhesion-medium layer in such a way that information is representable by means of the magnetic particles.

In various developments, the light-emitting component is at least a top emitter.

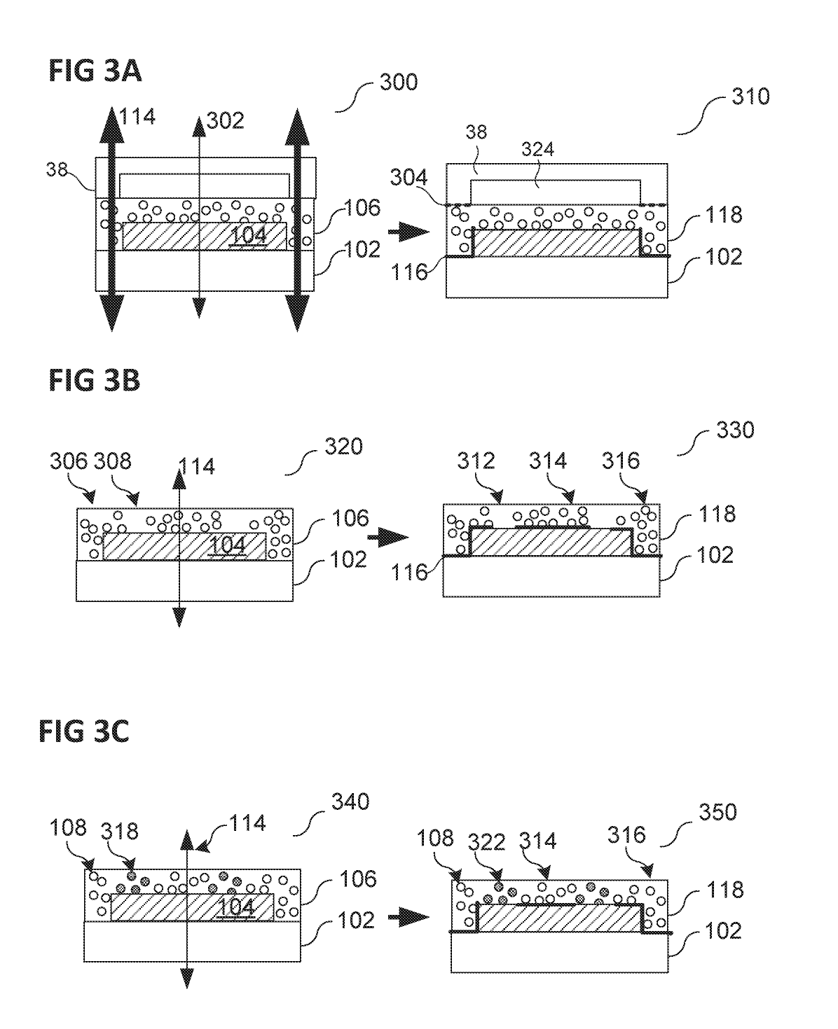

FIGS. 3A, 3B and 3C show, in schematic cross-sectional views, excerpts from a flow diagram of a method for producing an organic light-emitting component including a laterally structured adhesion-medium layer in accordance with various embodiments. FIGS. 3A, 3B and 3C illustrate developments of the method and of the organic light-emitting component such as have already been described above.

FIGS. 3A, 3B and 3C illustrate in greater detail examples described above in which the adhesion-medium layer 106 is formed in a laterally structured fashion, that is to say that a lateral structuring is formed in the adhesion-medium layer 106. Although the developments illustrated in FIGS. 3A-3C are illustrated in a manner isolated from one another, they can also be combined with one another.

As already described above, the adhesion-medium layer 106 can be formed in such a way, and/or the alternating magnetic field 114 can be configured in such a way, that the adhesion-medium layer 106 has a lateral structuring after the adhesive connection has been formed.

In the case of the development 300—illustrated in FIG. 3A—of applying 130 an alternating magnetic field 114 (see FIG. 1), a laterally inhomogeneous alternating magnetic field 114, 302 is used (illustrated by means of the different line thicknesses of the arrows in FIG. 3A). Furthermore, the organic light-emitting component after the process of forming 310 the at least one adhesive connection is illustrated (analogously to method step 140 in FIG. 1). The alternating magnetic field can be temporally and/or spatially inhomogeneous.

A first alternating magnetic field 114 is applied (locally) in a first region and has the effect, for example, that an adhesive connection 116 is formed between the adhesion-medium layer 106 and the electrically active region 104 and/or the substrate 102. The first region is for example an edge region of the organic light-emitting component, an optically active region or an optically inactive region.

A second alternating magnetic field 302 or substantially no alternating magnetic field is applied (locally) in a second region, and so this region is free of adhesive connection 116. The second region is arranged alongside the first region.

The second region includes for example a contact region 32, 34 of the organic light-emitting component for component-external contacting and/or at least one part of the light-emitting region of the organic light-emitting component.

For the case where the adhesion-medium layer is not cured above the contact region 32, 34 the adhesion-medium layer 106 can be removed from the contact region 32, 34 more simply and the contact region 32, 34 can thus be exposed more simply.

In the case of a non-cured adhesion-medium layer 106 above the optically active region, the non-cured adhesion-medium layer 106 acts as mechanical damping for the active region 104, for example with respect to an impact, a collision or an impression.

Optionally, a cover 38 can be provided on or above the adhesion-medium layer 106 (see FIG. 2). The cover 38 can be fixed by means of the cured adhesion-medium layer 106 in the first region on or above the substrate 102, for example by means of a first adhesive connection 116 and a second adhesive connection 304.

The further, second adhesive connection 304 can be formed before, after or during the first adhesive connection 116.

The cover 38 can cover the adhesion-medium layer 106 in the light-emitting region of the organic light-emitting component and protect it against direct contact. The adhesion-medium layer 106 can optionally be non-cured in the light-emitting region.

The cover 38 can bear on the adhesion-medium layer 106 in a substantially planar fashion (see FIG. 2) or can have a cavity 324 adjoining the adhesion-medium layer 106 (illustrated in FIG. 3A).

An encapsulation with a cover 38 having a cavity 324 is also referred to as cavity glass encapsulation. The cavity 324 is filled for example with a gas or getter material. In the light-emitting region of the organic light-emitting component, it is possible for the adhesion-medium layer 106 in the case of a cavity glass encapsulation, for example, to be free of a body-connecting effect, i.e. not to form a cohesive connection between the electrically active region 104 and the cover 38. The adhesion-medium layer 106 thus adjoins air, for example, in the region of the cavity 324.

In the case of the development 320—illustrated in FIG. 3B—of applying 130 an alternating magnetic field 114 (see FIG. 1) the magnetic material is firstly structured laterally before the alternating magnetic field is applied, such that at least one region of higher magnetizability 306 and at least one region of low magnetizability 308 are formed. The region of higher magnetizability 306 has for example a higher number density of particles composed of magnetizable material 108 compared with the region of low magnetizability 308. The region of low magnetizability 308 is for example free of magnetizable material 108.

Furthermore, the organic light-emitting component after the process of forming 330 the at least one adhesive connection is illustrated (analogously to method step 140 in FIG. 1).

By means of the laterally inhomogeneous distribution of the magnetizable material 108 in the adhesion-medium layer 106, in the light-emitting region it is possible to form for example a light-scattering region 314 alongside a non-light-scattering region 312. As a result, by way of example, information can be represented or a predefined emission characteristic can be realized as has already been described in greater detail above.

Alternatively or additionally, an adhesive connection can be formed in a region 316 at the edge or alongside the electrically active region. By means of this region it is possible for example to fix a cover 38 on the adhesion-medium layer 106 (see FIGS. 2 and 3A).

In the case of the development 320 illustrated in FIG. 3C of applying 130 an alternating magnetic field 114 (see FIG. 1) a first type of magnetizable material 108 and a second type of magnetizable material 318 are used, wherein the second magnetizable material has a smaller hysteresis area, i.e. lower inductive heating than the first magnetizable material 108.

Alternatively or additionally, a first type of magnetizable particles 108 and a second type of magnetizable particles 318 are provided in the adhesion-medium layer. The particles 318 of the second type have for example a larger average diameter than the particles of the first type 118. As a result, the particles of the first type 118 have a larger surface-to-volume ratio than the particles of the second type 318. As a result, the particles 118 of the first type, for example given the same material as the particles of the second type 318, have a greater heat flow than the particles of the second type 318. Consequently, in a high-frequency alternating magnetic field, the region of the adhesion-medium layer 106 including particles 108 of the first type can reach the temperature for forming the adhesive connection 116 and form the latter, while the region of the adhesion-medium layer 106 including particles of the second type 318 remains below said temperature. Alternatively, an adhesive connection is also formed in the region of the adhesion-medium layer including the particles 318 of the second type 318 (not illustrated).

Furthermore, the organic light-emitting component after the process of forming 350 the at least one adhesive connection 116 is illustrated (analogously to method step 140 in FIG. 1). By means of the different types of magnetizable particles 108, 318 having different average diameters, it is possible for example to realize a first light-scattering region 314 and a second light-scattering region 322, wherein these regions have a different degree of light scattering.

Alternatively or additionally, the region of the adhesion-medium layer 106 with adhesive connection 116 can have different optical properties compared with the region of the adhesion media arranged alongside without adhesive connection 116, for example a different refractive index, a different optical absorption or a different optical anisotropy. As a result, by way of example, with non-light-scattering magnetizable material 108, too, it is possible to represent information or to realize a predefined emission characteristic.

In an example 1, a method for producing an organic light-emitting component is provided. The method includes forming an electrically active region and applying an adhesion-medium layer on or above the electrically active region. The adhesion-medium layer includes a magnetic material distributed in an adhesion medium. The method furthermore includes applying an alternating magnetic field to the adhesion-medium layer, such that the adhesion medium forms at least one adhesive connection.

Example 2 is a method according to example 1, wherein the magnetic material and the adhesion medium are thermally coupled to one another.

Example 3 is a method according to example 1 or 2, wherein the adhesion medium is substantially transparent to visible light and at least part of the light emittable by the light-emitting component is emittable through the adhesion-medium layer.

Example 4 is a method according to any of examples 1 to 3, wherein the magnetic material is embedded as particles in the adhesion medium.

Example 5 is a method according to example 4, wherein the magnetic particles are formed such that they are light-scattering.

Example 6 is a method according to either of examples 4 and 5, wherein the magnetic particles are arranged in the adhesion medium with respect to a predefined direction and/or structure before the adhesive connection is formed.

Example 7 is a method according to any of examples 1 to 6, wherein an adhesive connection is formed between the adhesion medium and the electrically active region.

Example 8 is a method according to any of examples 1 to 7, the method furthermore including: forming a thin-film barrier layer on the electrically active region, and applying the adhesion-medium layer on the thin-film barrier layer, wherein an adhesive connection is formed between the adhesion medium and the thin-film barrier layer.

Example 9 is a method according to any of examples 1 to 8, the method furthermore including: arranging a cover on the adhesion-medium layer before the adhesion medium forms the adhesive connection, wherein a further adhesive connection is formed between the adhesion medium and the cover by means of the alternating magnetic field.

Example 10 is a method according to any of examples 1 to 9, wherein the alternating magnetic field is applied to the adhesion-medium layer in a predefined region, such that at least one adhesive connection is formed only in the predefined region.

Example 11 is a method according to any of examples 1 to 10, wherein the magnetic material is a ferrite and the magnetic material is demagnetized after the adhesive connection has been formed.

Example 12 is an organic light-emitting component, including: an electrically active region, and an adhesion-medium layer on or above the electrically active region, wherein the adhesion-medium layer includes magnetic particles embedded in an adhesive, wherein the magnetic particles are arranged in a predefined arrangement in the adhesion medium.

Example 13 is an organic light-emitting component according to example 12, wherein the adhesion-medium layer includes at least one adhesive connection in a predefined first region and a second region arranged alongside the first region is free of said adhesive connection.

Example 14 is an organic light-emitting component according to either of examples 12 and 13, wherein the magnetic particles are formed and arranged in the adhesion-medium layer in such a way that information is representable by means of the magnetic particles.

Example 15 is an organic light-emitting component according to any of examples 12 to 14, wherein the light-emitting component is formed at least as a top emitter.

Example 16 is a method for producing an organic light-emitting component, the method including: forming an electrically active region; applying an adhesion-medium layer on or above the electrically active region, wherein the adhesion-medium layer includes a magnetic material distributed in an adhesion medium, wherein the magnetic material is embedded as particles in the adhesion medium; and applying an alternating magnetic field to the adhesion-medium layer, such that the adhesion medium forms at least one adhesive connection, wherein an adhesive connection is formed between the adhesion medium and the electrically active region, wherein the adhesion-medium layer is formed in such a way, and/or the alternating magnetic field is configured in such a way that the adhesion-medium layer has a lateral structuring after the adhesive connection has been formed.

Example 17 is a method according to example 16, furthermore including: arranging a cover on the adhesion-medium layer before the adhesion medium forms the adhesive connection, wherein a further adhesive connection is formed between the adhesion medium and the cover by means of the alternating magnetic field.

Example 18 is a method according to either of examples 16 and 17, wherein the electrically active region is formed with an optically inactive region and an optically active region arranged alongside the optically inactive region, wherein the adhesion-medium layer includes at least one adhesive connection in the optically inactive region and the optically active region is free of said adhesive connection.

Example 19 is a method for producing an organic light-emitting component, the method including: forming an electrically active region, wherein the electrically active region is formed with an optically inactive region and an optically active region arranged alongside the optically inactive region; applying an adhesion-medium layer on or above the electrically active region, wherein the adhesion-medium layer includes a magnetic material distributed in an adhesion medium, wherein the magnetic material is embedded as particles in the adhesion medium; and arranging a cover on the adhesion-medium layer, applying an alternating magnetic field to the adhesion-medium layer, such that the adhesion medium forms at least one adhesive connection, wherein the adhesion-medium layer is formed in such a way and/or the alternating magnetic field is configured in such a way that the adhesion-medium layer has a lateral structuring after the adhesive connection has been formed, wherein an adhesive connection is formed between the adhesion medium and the cover at least in the optically inactive region and at least one part of the optically active region is free of adhesive connection.

Example 20 is a method according to example 19, wherein the magnetic particles are arranged in the adhesion medium with respect to a predefined direction and/or structure before the adhesive connection is formed.

Example 21 is a method according to either of examples 19 and 20, wherein the magnetic particles are formed and arranged in the adhesion-medium layer in such a way that information is representable by means of the magnetic particles.

Example 22 is a method according to example 21, wherein the information is representable or represented by means of a laterally different emission characteristic of the organic light-emitting component.

Example 23 is a method according to example 21 or 22, wherein the information is a symbol, lettering or a pictogram.

Example 24 is a method according to any of examples 19 to 23, wherein the alternating magnetic field is applied to the adhesion-medium layer in a first region, such that at least one adhesive connection is formed only in the first region and a second region arranged alongside the first region is free of said adhesive connection.

Example 25 is a method according to example 24, wherein the alternating magnetic field is inhomogeneous in such a way that the magnetic field strength is greater in the first region than in the second region.

Example 26 is a method according to example 24 or 25, wherein the adhesion-medium layer includes a first type of magnetic particles in the first region and a second type of magnetic particles in the second region, wherein the first type of magnetic particles has a different magnetic property compared with the second type of magnetic particles; and/or wherein the first type of magnetic particles has a different coupling area with the adhesion medium compared with the second type of magnetic particles.

Example 27 is a method according to any of examples 19 to 26, wherein the first region has a higher proportion by volume and/or a higher number density of magnetic particles than the second region.

Example 28 is a method according to any of examples 19 to 27, wherein the optically active region is surrounded by the optically inactive region.

Example 29 is a method according to any of examples 19 to 28, the method furthermore including: forming a thin-film barrier layer on the electrically active region, and applying the adhesion-medium layer on the thin-film barrier layer, wherein the adhesive connection is formed between the adhesion medium and the thin-film barrier layer.

Example 30 is a method according to any of examples 19 to 29, wherein the magnetic material is a ferrite and the magnetic material is demagnetized after the adhesive connection has been formed.

Example 31 is an organic light-emitting component, including: an electrically active region, and an adhesion-medium layer on or above the electrically active region, wherein the adhesion-medium layer includes magnetic particles embedded in an adhesion medium, wherein the magnetic particles are arranged in a predefined arrangement in the adhesion medium, wherein the adhesion-medium layer includes at least one adhesive connection in a predefined first region and a second region arranged alongside the first region is free of said adhesive connection.

Example 32 is an organic light-emitting component, including: an electrically active region including an optically inactive region and an optically active region arranged alongside the optically inactive region, an adhesion-medium layer on or above the electrically active region, wherein the adhesion-medium layer includes magnetic particles embedded in an adhesion medium, wherein the magnetic particles are arranged in a predefined arrangement in the adhesion medium, a cover on the adhesion-medium layer, wherein at least one adhesive connection, wherein the adhesion-medium layer includes an adhesive connection between the adhesion medium and the cover at least in the optically inactive region and at least one part of the optically active region is free of adhesive connection.

Example 33 is an organic light-emitting component according to example 31 or 32, wherein the magnetic particles are formed and arranged in the adhesion-medium layer in such a way that information is representable by means of the magnetic particles.

Example 34 is an organic light-emitting component according to any of examples 31 to 33, wherein the light-emitting component is formed at least as a top emitter.

By way of example, the organic light-emitting component may include a plurality or a multiplicity of light-emitting components and/or light-scattering layers.

While the embodiments disclosed have been shown and described in particular with reference to the specific embodiments, the person skilled in the art understands that various modifications in form and detail can be made, without departing from the spirit and scope of the embodiments disclosed, as defined by the appended claims. The scope of the embodiments disclosed is thus indicated by the appended claims and all modifications that come within the meaning and the range of equivalence of the claims are therefore intended to be encompassed.

### LIST OF REFERENCE SIGNS

100, 110, 120, 130, 140, 310, 320, 330, 340, 350—Method/method steps
102 Substrate
104 Electrically active region
106 Adhesion-medium layer
108, 318 Magnetic material/particles
112 Adhesion medium
114, 302 Alternating magnetic field
116, 304 Adhesive connection
118 Adhesion-medium layer with adhesive connection
1 Organic light-emitting component
16 First contact section
18 Second contact section
20 First electrode
21 Electrical insulation barrier
22 Organic functional layer structure
23 Second electrode
24 thin-film barrier layer
32 First contact region
34 Second contact region
38 Covering body
324 Cavity
312, 314, 316, 322 Lateral structuring

1. Method for producing an organic light-emitting component, the method comprising:
forming an electrically active region;
applying an adhesion-medium layer on or above the electrically active region, wherein the adhesion-medium layer comprises a magnetic material distributed in an adhesion medium, wherein the magnetic material is embedded as particles in the adhesion medium; and
applying an alternating magnetic field to the adhesion-medium layer, such that the adhesion medium forms at least one adhesive connection, wherein an adhesive connection is formed between the adhesion medium and the electrically active region,
wherein the adhesion-medium layer is formed in such a way, and/or the alternating magnetic field is configured in such a way that the adhesion-medium layer has a lateral structuring after the adhesive connection has been formed.

2. Method according to claim 1, the method furthermore comprising:
arranging a cover on the adhesion-medium layer before the adhesion medium forms the adhesive connection,
wherein a further adhesive connection is formed between the adhesion medium and the cover by means of the alternating magnetic field.

3. Method according to claim 1,
wherein the electrically active region is formed with an optically inactive region and an optically active region arranged alongside the optically inactive region, wherein the adhesion-medium layer comprises at least one adhesive connection in the optically inactive region and the optically active region is free of said adhesive connection.

4. Method according to claim 3,
wherein the optically active region is surrounded by the optically inactive region.

5. Method according to claim 1,
wherein the magnetic particles are arranged in the adhesion medium with respect to a predefined direction and/or structure before the adhesive connection is formed.

6. Method according to claim 1,
wherein the magnetic particles are formed and arranged in the adhesion-medium layer in such a way that information is representable by means of the magnetic particles.

7. Method according to claim 6,
wherein the information is representable by means of a laterally different emission characteristic of the organic light-emitting component.

8. Method according to claim 7,
wherein the information is a symbol, lettering or a pictogram.

9. Method according to claim 1,
wherein the alternating magnetic field is applied to the adhesion-medium layer in a first region, such that at least one adhesive connection is formed only in the first region and a second region arranged alongside the first region is free of said adhesive connection.

10. Method according to claim 9,
wherein the alternating magnetic field is inhomogenous in such a way that the magnetic field strength is greater in the first region than in the second region.

11. Method according to claim 10,
wherein the adhesion-medium layer comprises a first type of magnetic particles in the first region and a second type of magnetic particles in the second region,
wherein the first type of magnetic particles has a different magnetic property compared with the second type of magnetic particles; and/or
wherein the first type of magnetic particles has a different coupling area with the adhesion medium compared with the second type of magnetic particles.

12. Method according to claim 9,
wherein the first region has a higher proportion by volume and/or a higher number density of magnetic particles than the second region.

13. Method according to claim 1, the method furthermore comprising:
forming a thin-film barrier layer on the electrically active region, and
applying the adhesion-medium layer on the thin-film barrier layer, wherein the adhesive connection is formed between the adhesion medium and the thin-film barrier layer.

14. Method according to claim 1,
wherein the magnetic material is a ferrite and the magnetic material is demagnetized after the adhesive connection has been formed.

15. Method according to claim 1, the method furthermore comprising:
forming the electrically active region, wherein the electrically active region is formed with an optically inactive region and an optically active region arranged alongside the optically inactive region;
applying the adhesion-medium layer on or above the electrically active region;
arranging a cover on the adhesion-medium layer,
applying the alternating magnetic field to the adhesion-medium layer after arranging the cover, wherein an adhesive connection is formed between the adhesion medium and the cover at least in the optically inactive region and at least one part of the optically active region is free of adhesive connection.

16. Organic light-emitting component, comprising:
an electrically active region, and
an adhesion-medium layer on or above the electrically active region,
wherein the adhesion-medium layer comprises magnetic particles embedded in an adhesion medium,
wherein the magnetic particles are arranged in a predefined arrangement in the adhesion medium,
wherein the adhesion-medium layer comprises at least one adhesive connection in a predefined first region and a second region arranged alongside the first region is free of said adhesive connection.

17. Organic light-emitting component according to claim 16,
wherein the magnetic particles are formed and arranged in the adhesion-medium layer in such a way that information is representable by means of the magnetic particles.

18. Organic light-emitting component according to claim 16,
wherein the light-emitting component is formed at least as a top emitter.

19. Organic light-emitting component, comprising:
an electrically active region comprising an optically inactive region and an optically active region arranged alongside the optically inactive region,
an adhesion-medium layer on or above the electrically active region,
wherein the adhesion-medium layer comprises magnetic particles embedded in an adhesion medium,
wherein the magnetic particles are arranged in a predefined arrangement in the adhesion medium,
a cover on the adhesion-medium layer (118), wherein at least one adhesive connection, wherein the adhesion-medium layer comprises an adhesive connection between the adhesion medium and the cover at least in the optically inactive region and at least one part of the optically active region is free of adhesive connection.

20. Organic light-emitting component according to claim 19,
wherein the magnetic particles are formed and arranged in the adhesion-medium layer in such a way that information is representable by means of the magnetic particles.
